(19) United States
(12) Patent Application Publication
(10) Pub. No.: US 2009/0309182 A1
(43) Pub. Date: Dec. 17, 2009

(54) ELECTROSTATIC DISCHARGE PROTECTION STRUCTURE

(76) Inventors: Kung-Yen Su, San Jose, CA (US); Yaw Wen Hu, Cupertino, CA (US); Bomy Chen, Cupertino, CA (US); Kevin Gene-Wah Jew, Fremont, CA (US)

Correspondence Address: DLA PIPER LLP (US ), 2000 UNIVERSITY AVENUE, EAST PALO ALTO, CA, 94303-2248, US

(21) Appl. No.: 12/140,195

(22) Filed: Jun. 16, 2008

(51) Int. Cl. H01L 23/62

(52) U.S. Cl. 257/493; 257/E29.181

(57) ABSTRACT

A first embodiment of an Electrostatic Discharge (ESD) structure for an integrated circuit for protecting the integrated circuit from an ESD signal, has a substrate of a first conductivity type. The substrate has a top surface. A first region of a second conductivity type is near the top surface and receives the ESD signal. A second region of the second conductivity type is in the substrate, separated and spaced apart from the first region in a substantially vertical direction. A third region of the first conductivity type, heavier in concentration than the substrate, is immediately adjacent to and in contact with the second region, substantially beneath the second region. In a second embodiment, a well of a second conductivity type is provided in the substrate of the first conductivity type. The well has a top surface. A first region of the second conductivity type is near the top surface. A second region of the second conductivity type is in the well, substantially along the bottom of the well. A third region of the first conductivity type, is immediately adjacent to and in contact with the second region, substantially beneath the second region. A fourth region of the first conductivity type is in the well, along the top surface thereof, and spaced apart from the first region. The first region and the fourth region receive the ESD signal.

### TECHNICAL FIELD

The present invention relates to an electrostatic discharge (ESD) protection structure for an integrated circuit device, and more particularly where the level of protection, i.e. voltage at which the structure can sustain the application of an ESD signal, and the level at which the structure can dissipate the ESD signal can be controlled.

### BACKGROUND OF THE INVENTION

Structures to protect integrated circuit devices from the deleterious effects of an Electrostatic Discharge (ESD) signal are well known in the art. See for example U.S. Pat. No. 6,493,199. In such a structure, a well of N type conductivity is provided in a substrate of P type conductivity. P+ region and N+ region are formed in the N well. Finally, a N+ region is formed adjacent to the N well. The formation of such a structure appears to be unnecessarily complicated involving the use of a number of mask steps, which increases cost. Accordingly, it is one object of the present invention to simply the formation of an ESD protection structure.

### SUMMARY OF THE INVENTION

In the present invention, an Electrostatic Discharge (ESD) structure for an integrated circuit for protecting the integrated circuit from an ESD signal, has a substrate of a first conductivity type. The substrate has a top surface. A first region of a second conductivity type is near the top surface and receives the ESD signal. A second region of the second conductivity type is in the substrate, separated and spaced apart from the first region in a substantially vertical direction. A third region of the first conductivity type, heavier in concentration than the substrate, is immediately adjacent to and in contact with the second region, substantially beneath the second region.

### BRIEF DESCRIPTION OF THE DRAWINGS

FIG. 1 is a cross sectional view of a first embodiment of an ESD structure of the present invention.

FIG. 2 is a cross sectional view of a second embodiment of an ESD structure of the present invention.

### DETAILED DESCRIPTION OF THE INVENTION

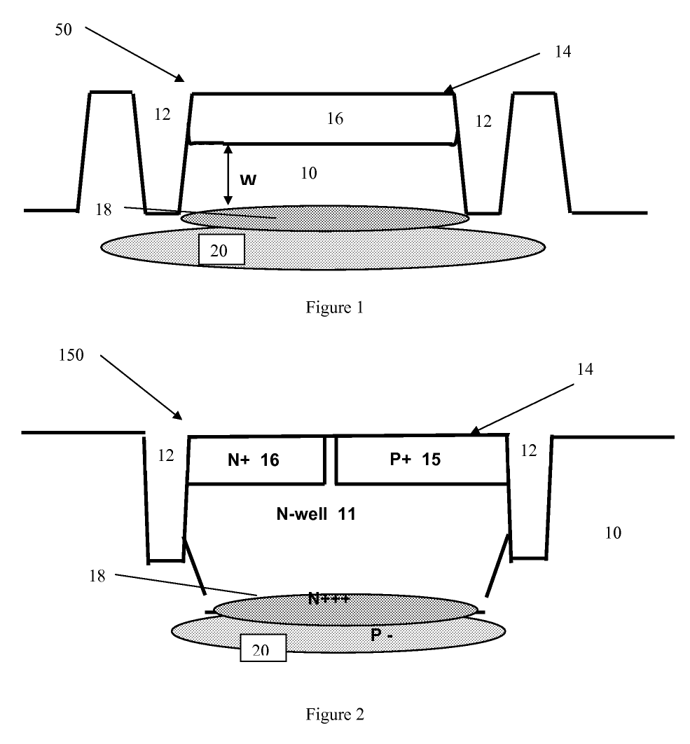

Referring to FIG. 1, there is shown a cross sectional view of a first embodiment of an ESD protection structure 50 of the present invention formed in a semiconductor substrate 10. The semiconductor substrate 10 is a of a first conductivity type. In a preferred embodiment, this is P type. The substrate 10 is characterized by having a top surface 14. The ESD protection structure 50 in the preferred embodiment is formed between STI regions 12 or between field oxide regions 12 so that the structure 50 is isolated. A first region 16 of a second conductivity type (such as N+ type) is formed along the surface 14 of the substrate 10, and receives the ESD signal. A second region 18 of the second conductivity type, i.e. N+, is formed in the substrate 10 and is beneath the first region 16, in a vertical direction from the top surface 14. As shown in FIG. 1, the second region 18 is separated from the first region 16 by a distance W. A third region 20 of the first conductivity type, i.e. P+ region, is formed also in the substrate 10 and is adjacent to, in contact with, and beneath the second region 18.

In the operation of the structure 50 of the present invention, when an input signal is applied to the first region 16, if the voltage thereof is not sufficiently high, i.e. it is not an ESD signal, then the signal would be processed in a conventional manner. However, if the ESD signal has a high voltage, then the voltage of the ESD signal would cause the ESD signal to punch through the substrate 10 between the first region 16 and the second region 18, where the signal is then dissipated. The second region 18 is connected to ground potential. Thus, in essence, the first region 16, the separation region 10, and the second region 18 form a bipolar transistor through which the ESD signal is dissipated to ground.

The punch through voltage of the ESD signal is mainly controlled by the concentration of the P type conductivity of the substrate 10 and by the distance W between the first region 16 and the second region 18. The location of the third region 20 and the second region 18 can be controlled by the energy of the ion implant that form those regions. In addition, those regions may be formed by epitaxial deposition, forming epi grown layers. Finally, the depth of the first region 16 below the top surface 14 can be controlled by the implanting energy of phosphorus and/or arsenic implants followed by a thermal anneal cycle. In the preferred embodiment, the first region 16 should be as close to the top surface 14 as possible. The contact of the second region 18 with the third region 20 becomes a degenerated metallurgical short.

Referring to FIG. 2 there is shown a cross sectional view of a second embodiment of an ESD protection structure 150 of the present invention formed in a semiconductor substrate 10. The second embodiment 150 is similar to the first embodiment 50, and thus the same numerals will be used to designate the same parts. The semiconductor substrate 10 is a of a first conductivity type. In a preferred embodiment, this is P type. A well 11 of a second conductivity type, N, is formed in the substrate 10. The well 11 is characterized by having a top surface 14. The well 11 in the preferred embodiment is formed between STI regions 12 or between field oxide regions 12 so that it is isolated. A first region 16 of a second conductivity type (such as N+ type), heavier in concentration than the well 11, is formed along the surface 14. Adjacent to the first region 16 along the surface 14 is a fourth region 15, of the first conductivity type, such P+. The first region 16 and the fourth region 15 collectively receive the ESD signal. A second region 18 of the second conductivity type, N+, heavier in concentration than the well 11, is formed along the bottom of the well 11 and is beneath the first region 16 and the fourth region 15, in a vertical direction from the top surface 14. As shown in FIG. 2, the second region 18 is separated from the first region 16 and the fourth region 15. A third region 20 of the first conductivity type, i.e. P+ region, is formed along the bottom of the well 11, and is adjacent to, in contact with and beneath the second region 18.

In the operation of the structure 50 of the present invention, when an input signal is applied to the first region 16 and the fourth region 15, if the voltage thereof is not sufficiently high, i.e. it is not an ESD signal, then the signal would be processed in a conventional manner. However, if the ESD signal has a high voltage, then the voltage of the ESD signal would cause the structure 150 to function as an SCR with the N well 11 break down voltage controlled by the doping concentration of the first conductivity type in the third region 20 beneath the second region 18. By adjusting the concentration of the P conductivity type, the SCR trigger voltage can be controlled to a desirable voltage. Again, similar to the first embodiment, the second region 18 is connected to ground potential.

Similar to the formation of the structure 50, the second region 18 and third region 20 of the protection structure 150 can be formed by epitaxial deposition, forming epi grown layers. Finally, the depth of the first region 16 and fourth region 15 below the top surface 14 can be controlled by the implanting energy of the dopant implants followed by a thermal anneal cycle. In the preferred embodiment, the first region 16 and the fourth region 15 should be as close to the top surface 14 as possible.

From the foregoing it can be seen that the ESD protection structure 50 or 150 of the present invention does not require the formation of a regions outside of the well, thereby saving processing steps.

What is claimed is:

1. An Electrostatic Discharge (ESD) structure for an integrated circuit for protecting the integrated circuit from an ESD signal, comprising:
a substrate of a first conductivity type, said substrate having a top surface;
a first region of a second conductivity type near the top surface for receiving the ESD signal;
a second region of the second conductivity type in the substrate, separated and spaced apart from the first region in a substantially vertical direction; and
a third region of the first conductivity type, heavier in concentration than the substrate, immediately adjacent to and in contact with the second region, substantially beneath the second region.

2. The structure of claim 1 wherein the distance between the first region and the second region is determinative of the voltage of the ESD signal to which the structure can protect.

3. The structure of claim 1 wherein the first conductivity type is P and the second conductivity type is N.

4. An Electrostatic Discharge (ESD) structure for an integrated circuit for protecting the integrated circuit from an ESD signal, comprising:
a substrate of a first conductivity type,
a well in said substrate of a second conductivity type, said well having a top surface;
a first region of the second conductivity type near the top surface for receiving the ESD signal;
a second region of the second conductivity type in the well, substantially near the bottom thereof;
a third region of the first conductivity type, immediately adjacent to and in contact with the second region, substantially beneath the second region; and
a fourth region of the first conductivity type in said well near the top surface, and spaced apart from the first region.
